(19) United States
(12) Patent Application Publication
(10) Pub. No.: US 2023/0333146 A1
(43) Pub. Date: Oct. 19, 2023

(54) CURRENT SENSOR FOR MEASURING BUS BAR ELECTRIC CURRENT

(71) Applicant: Schaeffler Technologies AG & Co. KG, Herzogenaurach (DE)

(72) Inventors: Linbo Tang, Baden-Baden (DE); Aurélien Zint, Haguenau (FR)

(73) Assignee: Schaeffler Technologies AG & Co. KG, Herzogenaurach (DE)

(21) Appl. No.: 18/011,662

(22) PCT Filed: May 12, 2021
(86) PCT No.: PCT/DE2021/100433

§ 371 Date: Feb. 16, 2023

(30) Foreign Application Priority Data
Jul. 3, 2020 (DE) 10 2020 117 557.4

(51) Int. Cl. G01R 15/20; G01R 15/18

(52) U.S. Cl. CPC G01R 15/207; G01R 15/186

(57) ABSTRACT

A current sensor for measuring an electric current of a bus bar includes a ferromagnetic core and a circuit board. The bus bar extends through the ferromagnetic core. The ferromagnetic core includes a first air gap having a first width and a second air gap having a second width. The first width is greater than the second width. The circuit board includes a single sensor chip or two spatially separated sensor chips. The circuit board positions the sensor chip or the sensor chips relative to the first air gap and the second air gap. The single sensor chip includes two spatially separated magnetic sensing points, or the two sensor chips each include one magnetic sensing point. Each magnetic sensing point is disposed in one of the first air gap or the second air gap.

### CROSS-REFERENCE TO RELATED APPLICATIONS

This application is the U.S. National Phase of PCT Appin. No. PCT/DE2021/100433 filed May 12, 2021, which claims priority to DE 102020117557.4 filed Jul. 3, 2020, the entire disclosures of which are incorporated by reference herein.

### TECHNICAL FIELD

The disclosure relates to a current sensor for measuring an electric current of a bus bar. The current sensor has a ferromagnetic core, which has formed a first air gap and a second air gap. The bus bar extends through the ferromagnetic core.

### BACKGROUND

The international patent application WO 2016/006410 A1 discloses a current sensor with a first and a second magnetic sensing unit. The two sensing units are arranged at positions where there is a signal-to-noise (S/N) ratio such that a ratio between the strength of a magnetic field generated by a current to be measured flowing through a current path and the strength of an external magnetic field is equal. A processing unit determines a normal operation state in a case where the sensing signal of the first magnetic sensing unit and the sensing signal of the second magnetic sensing unit approximately match one another. The processing unit determines that one of the first and second magnetic sensing units has failed in a case where the sensing signals do not match one another.

The international patent application WO 2016/148022 A1 discloses three magnetic sensors positioned on a first virtual line provided with two magnetic shields such that a value detected by the magnetic sensor is less likely to be influenced by the field of an external magnet. The magnetic sensors are separated by a conductor by a certain distance.

The international patent application WO 2008/107773 A1 discloses an open loop electric current sensor for measuring the electric current flowing in a primary conductor. The current sensor comprises a magnetic circuit with an air gap and a magnetic field sensing device positioned in the air gap. The magnetic field sensing device comprises a circuit board, a first magnetic field detector mounted on the circuit board, and a second magnetic field detector. The second magnetic field detector comprises a conductive coil formed on the circuit board, wherein the output signals of the first magnetic field detector and the second magnetic field detector are adapted for connection to a signal processing circuit, which generates an output signal (electric current) representative of the primary side.

Current sensors are used in many applications to measure direct and alternating current. The application in electromobility, such as for battery monitoring in the battery system or for motor control in the inverter, is becoming increasingly important.

There are two main features for current sensing with a current sensor: one is the compactness of the current sensor and the other is accuracy. These are two opposing requirements. High accuracy means a more complex design and usually takes up more design space. On the other hand, smaller sensor designs typically lose accuracy due to the lack of certain components, such as ferromagnetic shielding, or having too small of a sensing area.

Current sensors are used in power electronics units. A current sensor is used to measure DC current and typically three current sensors are used to measure AC current. The three AC sensors can also be replaced by a single AC sensor that has three measurement positions. Space is typically very limited in power electronics units as the available design space is limited due to customer requirements.

Sensor constructions with a sensor chip and a ferromagnetic flux concentrator as a C-shaped core or as a U-shaped shield are known. These ferromagnetic flux concentrators can concentrate the magnetic flux generated from the primary current (measurement variable) at the position of the sensor chip and shield the stray field from the outside.

### SUMMARY

The present disclosure, according to an exemplary embodiment, provides an accurate and compact current sensor in order to increase the accuracy and at the same time to reduce the costs and the space required for the current sensor.

In one embodiment, a current sensor for measuring the electric current of a bus bar comprises a ferromagnetic core, which has formed a first air gap and a second air gap. In one embodiment, the bus bar, whose electric current is measured, extends through a cutout in the ferromagnetic core. In one embodiment, the first air gap has a width and the second air gap has a width, wherein the width of the first air gap is greater than the width of the second air gap. A circuit board of the current sensor can carry a single sensor chip or two spatially separated sensor chips. The circuit board is used to position the sensor chips in relation to the first air gap and the second air gap. In the case that a single sensor chip is provided, the single sensor chip has two spatially separated magnetic sensing points. In the other case that two sensor chips are provided, the two sensor chips each have a magnetic sensing point. The magnetic sensing points are arranged in the first air gap and the second air gap of the ferromagnetic core.

It does not necessarily have to be the case that the width of the first air gap is greater than the width of the second air gap. Depending on the desired output characteristic, the ratio of the widths of the air gaps can be varied. The main thing is that the two measured signals of the current generated by the magnetic flux differ significantly from one another.

The advantage of the current sensor is that greater accuracy is achieved when measuring the current of the bus bar, the current sensor requires less installation space and the production costs of the current sensor are reduced.

The current sensor can have a housing for accommodating the ferromagnetic core and the circuit board. The housing can have two opposite end faces, each of which has a cutout formed, through which the bus bar extends.

The housing has the advantage that the ferromagnetic core and the circuit board are protected by the housing and the housing provides a guide for the bus bar and also a mount for the current sensor on the bus bar.

In one embodiment, the housing of the current sensor further comprises the electrical inputs/outputs of the current sensor. These inputs/outputs can be plugs or simply pins. The positions of the plugs or the pins on the housing can vary depending on the application design. In one embodiment, the sensor housing has a slot (cutout) for inserting the bus bar, in which the primary current to be measured flows. Inside the housing, the pins are connected to the (printed) circuit board. The circuit board can be provided with additional electrical components that are responsible for the electronic signal processing of the signal output from the sensor chip or sensor chips.

According to one embodiment of the current sensor, the width of the first air gap is twice the width of the second air gap. The advantage of the different widths of the two air gaps arranged parallel to one another is that this results in two different magnetic fluxes in the ferromagnetic core, and the magnetic flux between the air gaps must differ significantly from one another.

According to a further embodiment, the spatially separated sensor chips are of the same type and have the same range for an output voltage. The range for the output voltage should be 0.5 to 4.5V for higher resolution, but the disclosure is not limited to this. The accuracy of the current sensor can be increased due to the higher resolution from two areas (the first air gap and the second air gap).

The design of the ferromagnetic core can vary. Most important is a flux concentrator that separates into two air gaps with two different magnetic fluxes. The magnetic flux in the first air gap must differ significantly from the magnetic flux in the second air gap

According to one embodiment of the current sensor, the ferromagnetic core is formed in one piece. The ferromagnetic core has a cutout formed; for example, in the lower area following the second air gap. This means that the portion of the ferromagnetic core that also defines part of the cutout comprises the second air gap. Accordingly, the cutout of the ferromagnetic core encloses the bus bar except for the second air gap. The advantage of the one-piece ferromagnetic core is that it makes it easier to assemble the current sensor. In addition, the intensity of the concentrated flux density is increased in the one-piece ferromagnetic core compared to the background of the art.

According to a further embodiment, the ferromagnetic core of the current sensor is formed from two pieces. The ferromagnetic core consists of a first E-shaped core and a second E-shaped core, which are arranged in such a way relative to one another that the first air gap and the second air gap are formed. According to one embodiment, the ferromagnetic core consisting of the first E-shaped core and the second E-shaped core also has a cutout opposite the second air gap. The cutout in the ferromagnetic core serves to accommodate the bus bar, wherein the cutout spatially forms a distance from the second air gap, which is smaller than a width of the bus bar.

The two E-shaped cores lead to a lower flux concentration ratio than the one-piece core, which leads to a lower flux density within the two air gaps. However, the advantage of the current sensor designed in this way with the two E-shaped cores is that less hysteresis effect is seen and the cost and weight of the current sensor are reduced. In addition, the installation of the current sensor is made easier. Without the closed core, the current sensor can be plugged onto the bus bar and no longer has to be inserted through the slot or the closed cutout.

According to yet another embodiment, the ferromagnetic core consists of a first F-shaped core and a second F-shaped core, which are arranged in such a way relative to one another that the first air gap and the second air gap are formed. According to one embodiment, the ferromagnetic core consisting of the first F-shaped core and the second F-shaped core also has a cutout opposite the second air gap, which serves to accommodate the bus bar. The cutout of the ferromagnetic core is spatially provided opposite the second air gap and defines a distance that is greater than a width of the bus bar.

With the two F-shaped cores, a lower flux concentration ratio also results, resulting in a lower magnetic field within the two air gaps. However, the advantage of this design with the two F-shaped cores is that there is also a lower hysteresis effect. In addition, the cost and weight of the current sensor are reduced.

Another advantage is that the current sensor can be attached directly to the bus bar, since there is no horizontal core element in the lower area of the ferromagnetic core. The bus bar does not have to be laboriously inserted through the sensor.

The term current sensor means a sensor module that comprises a housing, the ferromagnetic core, at least one sensor chip, etc. The magnetic sensing point is a sensor element that has a magnetic measurement unit integrated in the sensor chip.

The first air gap and the second air gap in the ferromagnetic core result in a current sensor with two measurement ranges. One magnetic sensing point (measurement point) is for a low current range and another magnetic sensing point (measurement point) is for a high current range. Both current ranges can make full use of the output voltage range from 0.5 to 4.5V. The electronic processing logic, which is provided on the circuit board of the current sensor, for example, must decide whether the current range is high or low during the current measurement. The combination of both output signals can result in greater accuracy overall.

The ferromagnetic core is divided into two air gaps that have different distances. One of the magnetic sensing points is near the first air gap and the other magnetic sensing point is near the second air gap. The exact location of these magnetic sensing points can vary depending on the sensor chip technology. The magnetic sensing points are determined by magnetic sensor elements. According to one embodiment, a sensor chip with two magnetic sensing points (magnetic sensor elements) or two sensor chips each with one magnetic sensing point (magnetic sensor element) is/are used. The position of the magnetic sensing points in the first or second air gap also depends on the sensor types used. The sensor chip technology can be based, for example, on the Hall effect, the magnetic resistance or a similar technology.

In the case of using two sensor chips, it is most important that two identical sensor chips with different programmed amplification factors are used.

The magnetic flux density in the second air gap must be higher than the magnetic flux density in the first air gap. The second air gap must therefore be shorter than or at least equal to the first air gap, since the magnetic resistance decreases with the length of the air gap. The horizontal distance between the two air gaps affects the sensing points. It must be larger than 4 mm to ensure that the measured signals can be distinguished from one another. The thickness of the two air gaps must be high enough to ensure that the positioning of the sensor chip or the magnetic sensing points within the respective air gap is contained within the required tolerances. The cross-section of the ferromagnetic core in the area of the two air gaps must be larger than the sensor chip that is inserted into the air gap. Within the two air gaps of the ferromagnetic core, the sensor chips or the magnetic sensing points can be placed within the middle of the air gaps. However, the placements can vary based on application design.

### BRIEF DESCRIPTION OF THE DRAWINGS

With reference to the accompanying drawings, the disclosure and its advantages will now be explained in more detail by means of exemplary embodiments, without thereby limiting the disclosure to the exemplary embodiment shown. The proportions in the figures do not always correspond to the real proportions, since some shapes are simplified and other shapes are shown enlarged in relation to other elements for better illustration.

FIG. 1 shows a perspective view of a current sensor for measuring the electric current of a bus bar.

FIG. 2 shows a side view of the current sensor from FIG. 1.

FIG. 3 shows a front view of an exemplary embodiment of internal structure of the current sensor without the protective housing.

FIG. 4 shows a perspective view of the internal structure of the current sensor from FIG. 3.

FIG. 5 shows a side view of the internal structure of the current sensor from FIG. 3.

FIG. 6 shows a representation of the dimensions of the housing for the current sensor.

FIG. 7 shows a representation of the dimensions of the ferromagnetic core of the current sensor for concentrating the magnetic flux.

FIG. 8 shows a representation of the dimensions of the positioning of the sensor chips in the ferromagnetic core of the current sensor.

FIG. 9 shows a representation of the result of the simulation of the magnetic field distribution of the flux in the ferromagnetic core.

FIG. 10 shows the geometry of the ferromagnetic core for the FEM simulation.

FIG. 11 shows the flux density as a function of the distance from the bus bar at 1000 A.

FIG. 12 shows the flux density as a function of the primary current at a maximum current of 1000 A.

FIG. 13 shows another exemplary embodiment of the internal structure of the current sensor.

FIG. 14 shows another exemplary possible embodiment of the internal structure of the current sensor.

FIG. 15 shows output voltages for each measurement range as a function of the primary current.

### DETAILED DESCRIPTION

Identical reference numerals are used for elements of the disclosure that are the same or have the same effect. Furthermore, for the sake of clarity, only those reference numerals that are necessary for the description of the respective figure are shown in the individual figures. The figures merely represent exemplary embodiments of the disclosure without, however, restricting the disclosure to the exemplary embodiments shown.

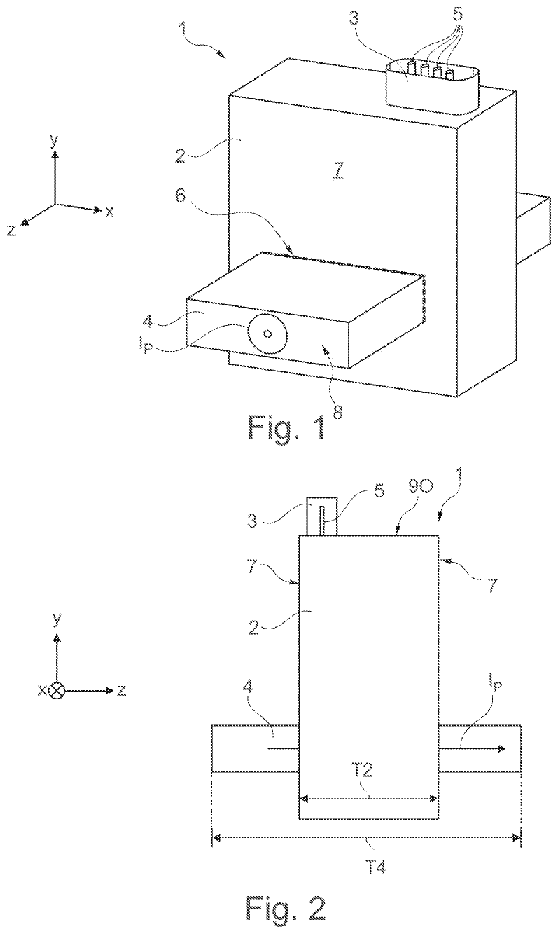

FIG. 1 shows a perspective view of a current sensor 1 for measuring an electric current IP of a bus bar 4. The electric current IP runs in a Z-direction Z in the representation shown here. The current sensor 1 comprises a housing 2 to which a plug connection 3 for inputs and outputs of the current sensor 1 is attached. The plug connection 3 comprises multiple pins 5, for example. The position of the plug connection 3 and the number of pins 5 can vary depending on the application design of the current sensor 1. The housing 2 of the current sensor 1 has a cutout 6 (indicated by the dashed line) formed on both opposite end faces 7, through which the bus bar 4 extends and thus extends through the housing 2. The electric current IP to be measured flows in the bus bar 4. The shape of the cutout 6 in the housing 2 essentially corresponds to the cross-sectional shape 8 of the bus bar 4.

FIG. 2 shows a side view of the current sensor 1 from FIG. 1. It can be clearly seen from the side view that the bus bar 4 extends through the housing 2. The housing 2 has a depth T2 and the bus bar 4 has a depth T4. The depth T4 of the bus bar 4 is greater than the depth T2 of the housing 2. Consequently, the bus bar 4 extends through the two opposite end faces 7 of the housing 2. The plug connection 3 with the pins 5 is provided on an upper side 9O of the housing 2.

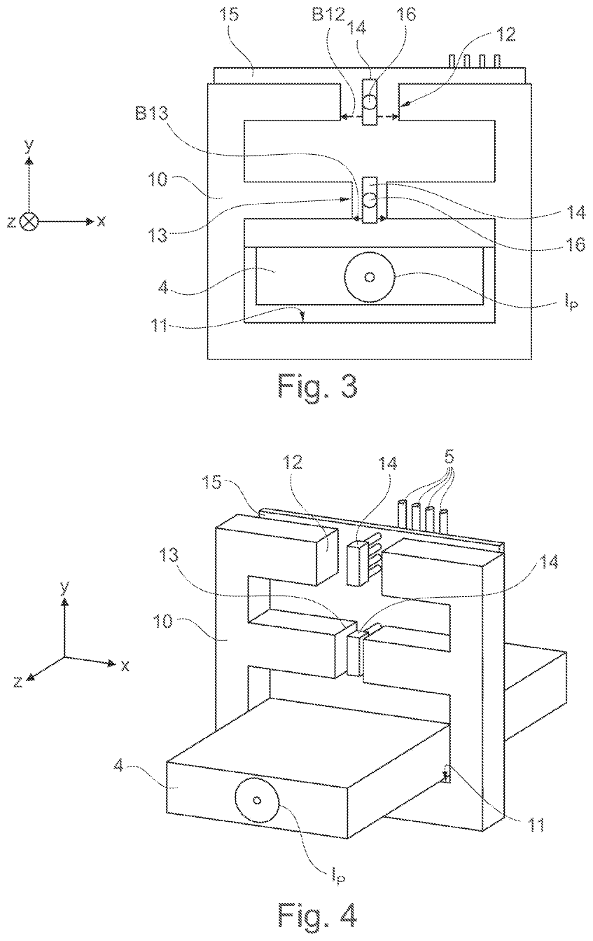

FIG. 3 shows a front view of an internal structure of the current sensor 1, and FIG. 4 shows a perspective view of the internal structure of the current sensor 1 without the protective housing 2 according to an exemplary embodiment of the current sensor 1. The internal structure of the current sensor 1 comprises a ferromagnetic core 10, which acts as a magnetic flux concentrator to improve the flux density generated by the current IP flowing through the bus bar 4. The ferromagnetic core 10 has formed a cutout 11 through which the bus bar 4 extends. According to the embodiment shown here, the bus bar 4 is at a distance from the cutout 11. Furthermore, the ferromagnetic core 10 has formed a first air gap 12 and a second air gap 13. A sensor chip 14 protrudes into each of the first air gap 12 and the second air gap 13. As can be seen from the representation in FIG. 4, the sensor chips 14 are attached to a circuit board 15 in such a way that when the circuit board 15 is positioned in relation to the ferromagnetic core 10, the two sensor chips 14 are located in the first air gap 12 and in the second air gap 13 of the ferromagnetic core 10, respectively. The circuit board 15 is supported on the bus bar 4. Furthermore, the circuit board 15 comprises the multiple pins 5, which form part of the plug connection 3 shown in FIG. 1 on the upper side 9O of the housing 2, to provide an electrical connection to outside of the housing 2.

As can be seen from the illustration in FIG. 3, the ferromagnetic core 10 (for example Fe core) is fitted around the bus bar 4 in order to concentrate the magnetic flux. The first air gap 12 has a width B12. The second air gap 13 has a width B13. In the embodiment shown here, the width B12 of the first air gap 12 is greater than the width B13 of the second air gap 13. As can be seen from FIGS. 3 and 4, the respective sensor chip 14 (magnetic sensor element) is arranged in the first air gap 12 and in the second air gap 13 in order to measure the magnetic field. The magnetic field to be measured is proportional to the electric current I_{P} (primary current) in the bus bar 4. Consequently, the sensor chip 14 in the first air gap 12 measures in a low current range and the sensor chip 14 in the second air gap 13 measures in a high current range. A person skilled in the art would understand that the design of the ferromagnetic core 10 can vary. The embodiment of the ferromagnetic core 10 shown in FIGS. 3 and 4 is for descriptive purposes only and should not be construed as a limitation of the disclosure. Most importantly, the ferromagnetic core 10 (flux concentrator) generates two different magnetic fluxes by means of the first air gap 12 and the second air gap 13, which are clearly different from one another.

In order to measure the magnetic flux, the sensor chip 14 is arranged in the first air gap 12 in such a way that a magnetic sensing point 16 of the sensor chip 14 is located in the first air gap 12. The sensing point 16 defines the physical position where the sensor chip 14 or the sensor chips 14 is/are to be placed. A magnetic sensing point 16 of the other sensor chip 14 is also located in the second air gap 13. The exact location of these magnetic sensing points 16 can vary depending on the sensor chip technology. A sensor chip 14 with two magnetic sensor elements or at least two sensor chips 14 can be used at the sensing points 16 as possible designs. The sensor chip technology can be based, for example, on the Hall effect, magnetic resistance or similar technologies.

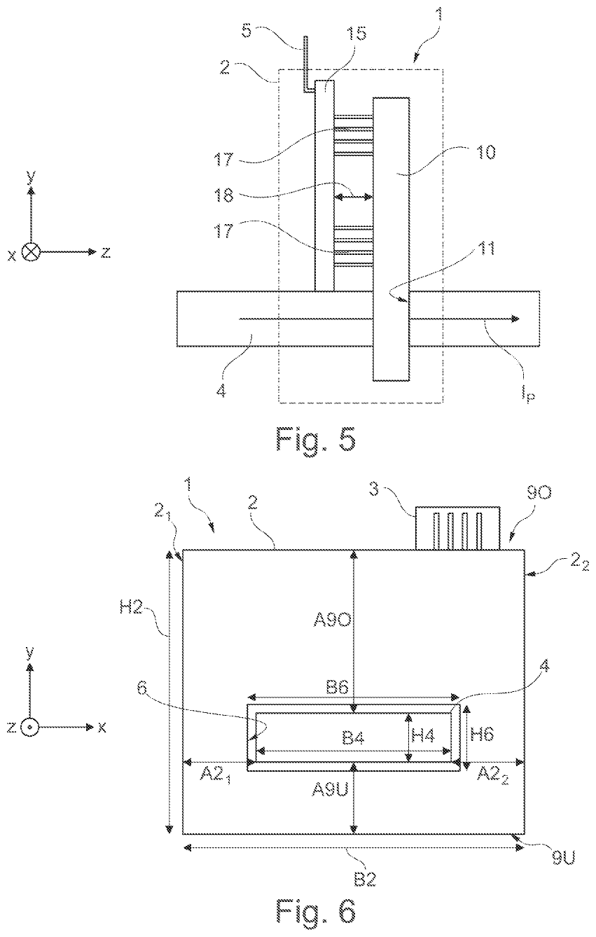

FIG. 5 shows a side view according to the exemplary embodiment of the internal structure of the current sensor 1 from FIG. 3. The usual housing 2 of the current sensor 1 is shown in dashed lines in order to clarify the internal structure of the current sensor 1. The bus bar 4 reaches through the cutout 11 of the ferromagnetic core 10. The circuit board 15 is connected to the one sensor chip 14 or the two sensor chips 14 with corresponding pins 17. The one sensor chip 14 with the two magnetic sensing points 16 (see FIG. 3) or the two sensor chips 14 with one sensing point 16 each are positioned in the ferromagnetic core 10. The circuit board 15 sits on the bus bar 4 and is arranged at a distance 18 from the ferromagnetic core 10. The circuit board 15 further comprises the pins 5 for the electrical connection to the outside of the housing 2. The circuit board 15 with additional electrical components (not shown), if necessary, is responsible for the electronic signal processing after the signal has been output by the sensor chip(s) 14.

FIG. 6 shows the dimensions of the bus bar 4 and the housing 2 of the current sensor 1 according to an exemplary embodiment. As the bus bar 4 has to be inserted into the housing 2 through the cutout 6 (slot), the cutout 6 in the housing 2 must be larger than the bus bar 4. The cutout 6 of the housing 2 has a width B6 and a height H6. The bus bar 4 has a width B4 and a height H4. As can be seen from FIG. 6, the width B4 and the height H4 of the bus bar 4 are each smaller than the width B6 and the height H6 of the cutout 6 in the housing 2, respectively. The upper side 9O and a lower side 9U of the housing 2 are spaced apart from one another by a height H2. A first side wall 2₁ and a second side wall 2₂ of the housing 2 are spaced apart from one another by a width B2. The bus bar 4 inserted into the housing 2 is spaced apart from the first side wall 2₁ by a distance A2₁ and from the second side wall 2₂ by a distance A2₂. Furthermore, the bus bar 4 is spaced apart from the upper side 9O of the housing 2 by a distance A9O and from the lower side 9U of the housing 2 by a distance A9U.

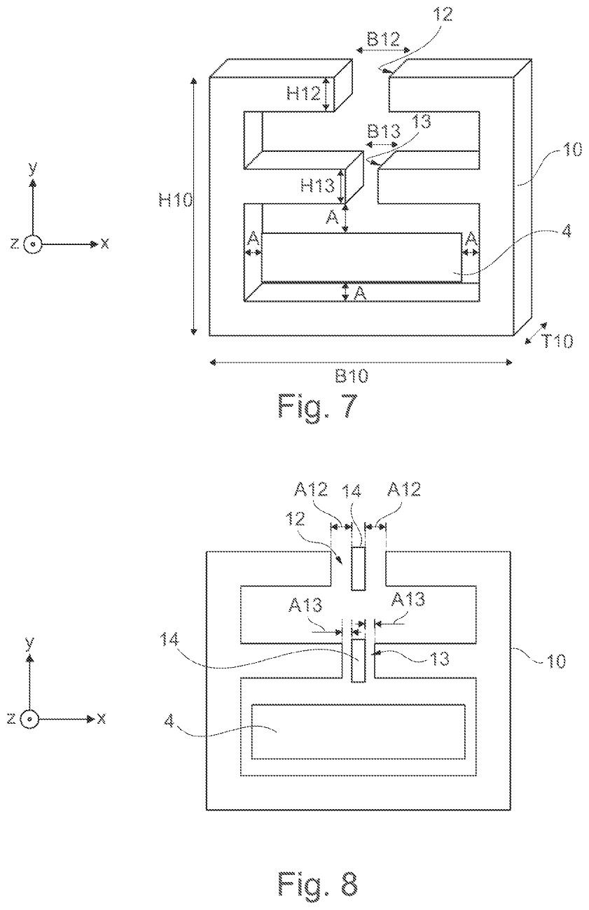

FIG. 7 shows a representation of the dimensions of the ferromagnetic core 10 of the current sensor 1 for concentrating the magnetic flux according to an exemplary embodiment. The ferromagnetic core 10 has a height H10, a width B10 and a depth T10. The height H10, the width B10 and the depth T10 of the ferromagnetic core 10 are each smaller than the height H2, the width B2 and the depth T2 of the housing 2 (not shown in FIG. 7), respectively. The bus bar 4 extends through the ferromagnetic core 10 at a distance A. The first air gap 12 has the width B12 and the second air gap 13 has the width B13. The width B12 of the first air gap 12 is greater than the width B13 of the second air gap 13.

The flux density at each of the magnetic sensing points 16 (see FIG. 3) depends on the width B12 of the first air gap 12 and the width B13 of the second air gap 13, respectively. In view of this, the low current range can be measured in the first air gap 12 and the high current range can be measured in the second air gap 13. The flux density in the first air gap 12 must be lower than the flux density in the second air gap 13. Therefore, the first air gap 12 must be wider or at least equal to the width B13 of the second air gap 13 since the magnetic resistance decreases with the width of the air gap.

FIG. 8 shows a representation of the dimensions of the positioning of the sensor chips 14 in the ferromagnetic core 10 of the current sensor 1 according to an exemplary embodiment. In the first air gap 12, the sensor chip 14 positioned there has a distance A12 on both sides from the ferromagnetic core 10. In the second air gap 13, the sensor chip 14 positioned there has a distance A13 on both sides from the ferromagnetic core 10. The sensor chips 14 should preferably be placed in the center of the first air gap 12 and the second air gap 13, respectively. However, the placement of the sensor chips 14 can deviate from the center placement depending on the application design.

The horizontal distance A12 or A13 between the first air gap 12 or the second air gap 13 and the sensor chip(s) 14 positioned there has an influence on the sensing points 16 (see FIG. 3). The horizontal distance A12 or A13 must be greater than 4 mm to ensure that the measured signals can be distinguished from one another. The height H12 of the first air gap 12 or the height H13 of the second air gap 13 (see FIG. 7) of the ferromagnetic core 10 must be high enough to ensure that the positioning of the sensor chips 14 within the air gaps 12 or 13 is possible within the required tolerances. The depth T10 of the ferromagnetic core 10 must be greater than a structural depth (not shown) of the sensor chip 14.

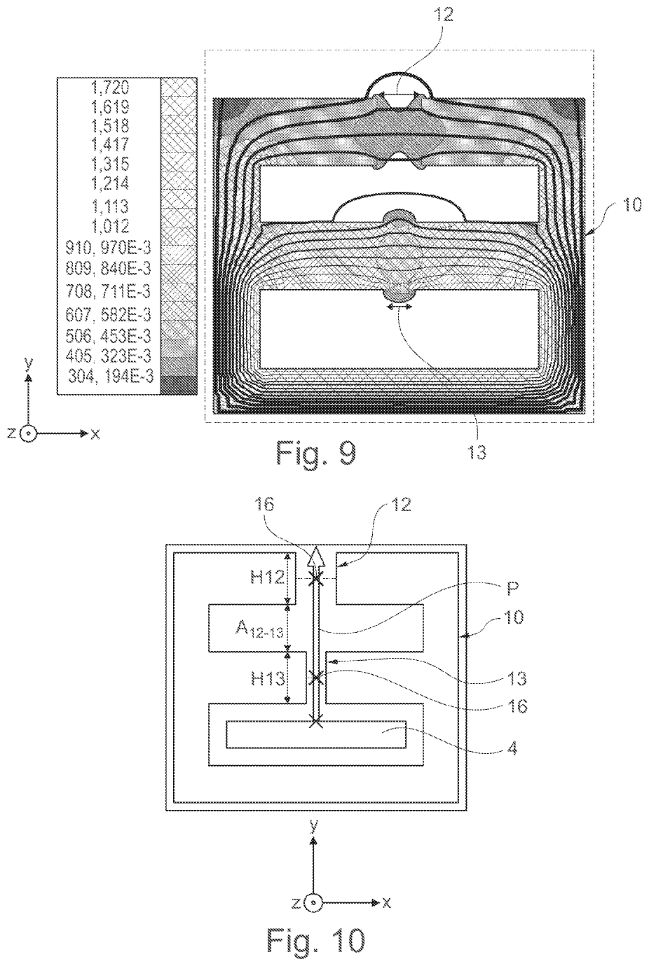

FIG. 9 shows a representation of a result of a 2D-FEM simulation of the flux in the ferromagnetic core 10. In this simulation of the current sensor 1 (not shown here), an electric current I_{P} (primary current) of 1000 A is assumed. In this simulation, the length of the second air gap 13 is two times shorter than that of the first air gap 12. The flux density in the first air gap 12 and in the second air gap 13 is homogeneous. The flux density in the second air gap 13 is higher than the flux density in the first air gap 12. In particular, in the exemplary embodiment of the ferromagnetic core 10 shown here, the flux density in the second air gap 13 is twice as high as in the first air gap 12.

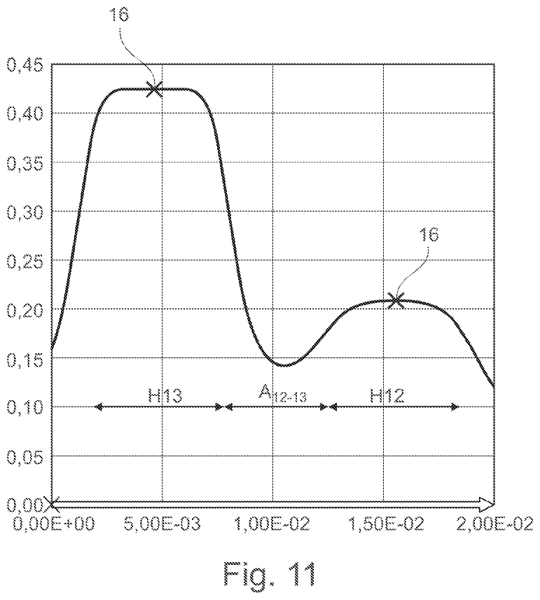

FIG. 10 shows the geometry of the ferromagnetic core 10 for the FEM simulation according to an exemplary embodiment. The magnetic sensing points 16 are arranged in the center of the first air gap 12 and the second air gap 13, respectively. The first air gap 12 has the height H12. The second air gap 13 has the height H13. Furthermore, a distance A₁₂₋₁₃ between the two air gaps 12 and 13 is also shown. The aforementioned parameters have an influence on the positioning tolerance (measurable positions) of the sensor chips 14 within the air gaps 12 and 13. The arrow P shows the direction of a Y-direction Y from the original position (bus bar 4) to the limits of the ferromagnetic core 10. The arrow P represents a distance to the bus bar 4.

FIG. 11 shows the flux density (Tesla) as a function of the distance (mm) from the bus bar 4 (identified by the arrow P). A constant primary current I_{P} of 1000 A flows through the bus bar 4. The flux density for the sensing point 16 in the second air gap 13 with the height H13 is twice as high as the flux density for the sensing point 16 in the first air gap 12 with the height H12. Within the air gaps 12 and 13, the flux density is homogeneous. Large heights H12 or H13 of the air gaps 12 or 13 and a greater horizontal distance A₁₂₋₁₃ can deliver a stable sensor signal.

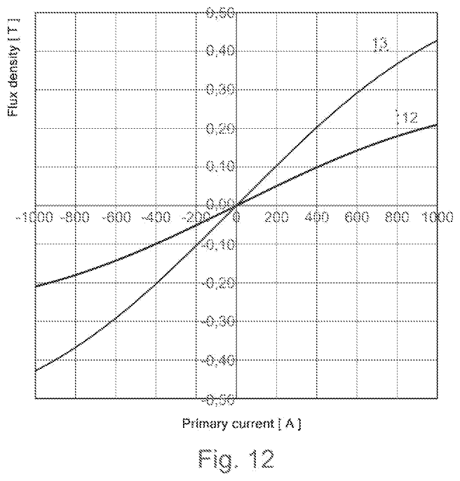

FIG. 12 shows the flux density as a function of the primary current I_{P} up to a maximum current of 1000 A. The flux density (Tesla) is shown as a function of the primary current (Ampere). The flux density is measured or simulated at the sensing points 16 in the first air gap 12 or in the second air gap 13 (see FIG. 10).

In this simulation, the second air gap 13 is two times shorter than the first air gap 12. As a result, the flux density in the second air gap 13 is twice as high as the flux density in the first air gap 12.

If the second air gap 13 is x times shorter than the first air gap 12, the flux density in the second air gap 13 is generally x times higher than the flux density in the first air gap 12.

As can be seen from FIG. 12, the relationship between the primary current I_{P} and the flux density is almost linear and has only small hysteresis errors. The two curves have the same shape but different amplification or sensitivity: The sensitivity at the sensing point 16 in the second air gap 13 is approximately twice that at the sensing point 16 in the first air gap 12. On the one hand, this leads to a better sensitivity for the low current range compared to the high current range. On the other hand, due to the higher sensitivity, the sensing point 16 in the second air gap 13 could saturate earlier for the low current range when the low current range is exceeded. The electronic signal processing of the current sensor should detect the saturation and switch to the sensor chip 14 in the first air gap 12 to measure the high current range.

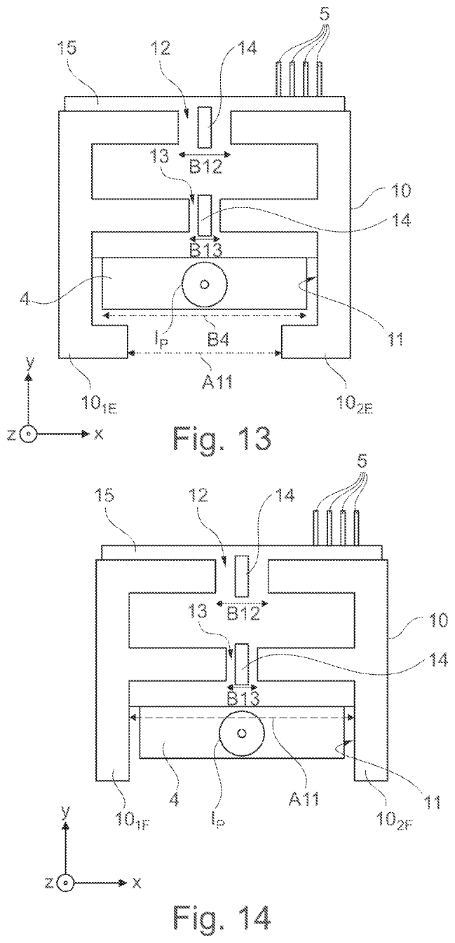

FIG. 13 shows another exemplary embodiment of the structure of the ferromagnetic core 10, which is arranged in the housing 2 (not shown here) of the current sensor 1. The ferromagnetic core 10 consists of a first E-shaped core 10_{1E} and a second E-shaped core 10_{2E}. The first E-shaped core 10_{1E} and the second E-shaped core 10_{2E} are arranged relative to one another in such a way that the first air gap 12 and the second air gap 13 are formed, respectively. Likewise, a cutout 11 of the ferromagnetic core 10 is formed, which accommodates the bus bar 4. The cutout 11 defines a distance A11, opposite from the second air gap 13, which is smaller than the width B4 (see also FIG. 6) of the bus bar 4.

This design of the ferromagnetic core 10 offers a lower flux concentration ratio than the entire ferromagnetic core 10 as illustrated in FIGS. 3 and 4. This exemplary embodiment described here consequently leads to a lower flux density within the first air gap 12 or the second air gap 13, respectively. An advantage of this embodiment is a lower hysteresis effect and a reduction in cost and weight.

FIG. 14 shows a further exemplary embodiment of the internal structure of the current sensor 1. This embodiment of the ferromagnetic core 10 comprises a first F-shaped core 10_{1F} and a second F-shaped core 10_{2F}. The first F-shaped core 10_{1F} and the second F-shaped core 10_{2F} are arranged relative to one another in such a way that the first air gap 12 and the second air gap 13 are formed, respectively. Likewise, a cutout 11 of the ferromagnetic core 10 is formed, which accommodates the bus bar 4. The cutout 11 defines a distance A11, opposite from the second air gap 13, which is greater than the width B4 (see FIG. 6 or 13) of the bus bar 4.

As already mentioned in the description of FIG. 13, the first F-shaped core 10_{1F} and the second F-shaped core 10_{2F} also result in a lower flux concentration ratio compared to the ferromagnetic core 10 of FIGS. 3 and 4. The current embodiment results in a lower magnetic field within the first air gap 12 and the second air gap 13, respectively. The sensor chip 14 or the sensor chips 14 with the magnetic sensing points 16 for registering the magnetic field must be more sensitive. As already mentioned in the description of FIG. 13, this embodiment has a lower hysteresis effect. Furthermore, the cost and the weight are reduced. In addition, since the first F-shaped core 10_{1F} and the second F-shaped core 10_{2F} do not have a horizontal core element, it is possible to fix the current sensor 1 to the bus bar 4 directly. The bus bar 4 therefore no longer needs to be laboriously guided through the current sensor 1, which makes assembly easier.

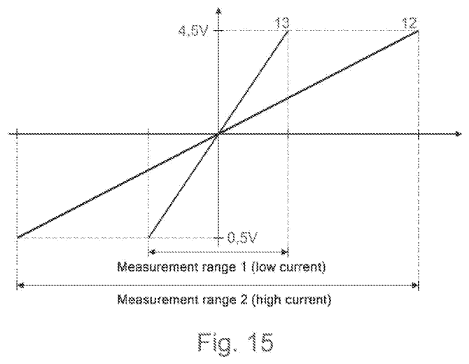

FIG. 15 shows output voltages for each measurement range as a function of the primary current IP. The output voltages Vₒᵤₜ for each measurement range (considered as the same range Vₒᵤₜ=0.5, . . . , 4.5V) are plotted as a function of the primary current I_{P}. The two sensor chips 14 are of the same type, but with different amplification factors. The amplification factor between the two sensor chips 14 is positive. This amplification factor is to be selected according to the desired measurement ranges, but also according to the factor that represents the width ratio between the second air gap 13 and the first air gap 12. Since the output voltage ranges are the same, the maximum output voltages must also be the same. If currents up to a current I_{Pmax} can be measured with the sensor chip 14 in the first air gap 12, currents up to a current I_{Pmax/x} can be measured with the sensor chip 14 in the second air gap 13. Here x represents the width ratio between the first air gap 12 and the second air gap 13. The sensor chips 14 are of the same type. This means that the total full-scale error should be the same. However, since the sensitivity is different, the accuracy of the measurement in the second air gap 13 is increased. The increase in accuracy is therefore proportional to the width ratio between the second air gap 13 and the first air gap 12.

It is believed that the present disclosure and many of the advantages noted therein will be understandable from the preceding description. It will be apparent that various changes in the shape, construction and arrangement of the components can be made without departing from the disclosed subject matter. The form described is illustrative only and it is the intent of the appended claims to comprise and incorporate such changes. Accordingly, the scope of the disclosure should be limited only by the appended claims.

### LIST OF REFERENCE NUMERALS

1 Current sensor

2 Housing

21 First side wall

22 Second side wall

3 Plug connection

4 Bus bar

5 Pin

6 Cutout of the end faces of the housing

7 End face

8 Cross-sectional shape

9O Upper side

9U Lower side

10 Ferromagnetic core

10_{1E} First E-shaped core

10_{2E} Second E-shaped core

10_{1F} First F-shaped core

10_{2F} Second F-shaped core

11 Cutout of the ferromagnetic core

12 First air gap

13 Second air gap

14 Sensor chip

15 Circuit board

16 Magnetic sensing point

17 Pin

18 Distance

A Distance

A2₁ Distance

A2₂ Distance

A9O Distance

A9U Distance

A11 Distance

A12 Distance

A13 Distance

A₁₂₋₁₃ Distance

B2 Width

B4 Width

B6 Width

B10 Width

B12 Width

B13 Width

H2 Height

H4 Height

H6 Height

H10 Height

H12 Height

H13 Height

I_{P} Electric current

P Arrow

T2 Depth

T4 Depth

T10 Depth

X X-direction

Y Y-direction

Z Z-direction

1. A current sensor for measuring an electric current of a bus bar comprises:
a ferromagnetic core including a first air gap having a first width and a second air gap having a second width, the first width being greater than the second width; and
a circuit board including a single sensor chip or two spatially separated sensor chips, the circuit board positions the sensor chip or the sensor chips relative to the first air gap and the second air gap;
wherein the single sensor chip has two spatially separated magnetic sensing points or the two sensor chips each have a magnetic sensing point, and each magnetic sensing point is arranged in one of the first air gap or the second air gap;
wherein the bus bar extends through the ferromagnetic core.

2. The current sensor according to claim 1, further comprising a housing accommodating the ferromagnetic core the circuit board.

3. The current sensor according to claim 2, wherein the housing includes two opposite end faces, the opposite end faces each have a cutout through which the bus bar extends.

4. The current sensor according to a claim 1, wherein the first width is two times larger than the second width.

5. The current sensor according to claim 1, wherein the two spatially separated sensor chips are of a same type and have a same range for an output voltage.

6. The current sensor according to claim 1, wherein the ferromagnetic core is one piece and has a cutout that encloses the bus bar except for at the second air gap.

7. The current sensor according to claim 1, wherein the ferromagnetic core is two pieces and includes a first E-shaped core and a second E-shaped core arranged in such a way relative to each other that the first air gap and the second air gap are formed.

8. The current sensor according to claim 7, wherein the ferromagnetic core defines a cutout for accommodating the bus bar, the cutout forming a distance, opposite from the second air gap (13), that is smaller than a width of the bus bar.

9. The current sensor according to claim 1, wherein the ferromagnetic core is two pieces and includes a first F-shaped core and a second F-shaped core arranged in such a way relative to each other that the first air gap and the second air gap are formed.

10. The current sensor according to claim 9, wherein the ferromagnetic core defines a cutout for accommodating the bus bar, the cutout forming a distance opposite from the second air gap (13), that is greater than a width of the bus bar.

11. A current sensor, comprising:
a ferromagnetic core forming:
a first air gap having a first width;
a second air gap having a second width, the first width being greater than the second width; and
a cutout;
a bus bar extending through the cutout; and
a sensor chip having a magnetic sensing point, the magnetic sensing point being arranged in one of the first air gap or the second air gap.

12. The current sensor of claim 11, wherein the sensor chip includes a further magnetic sensing point spaced from the magnetic sensing point, the further magnetic sensing point being arranged in the other of the first air gap or the second air gap.

13. The current sensor of claim 11, further comprising a further sensor chip having a further magnetic sensing point, the further magnetic sensing point being arranged in the other of the first air gap or the second air gap.

14. The current sensor of claim 11, wherein the second air gap extends to the cutout.

15. The current sensor of claim 14, wherein the cutout encloses the bus bar except for at the second air gap.

16. The current sensor of claim 14, wherein the ferromagnetic core includes a first E-shaped core and a second E-shaped core arranged in such a way relative to each other so as to form that the first air gap and the second air gap.

17. The current sensor of claim 16, wherein the cutout forms a distance, opposite the second air gap, that is less than a width of the bus bar.

18. The current sensor of claim 14, wherein the ferromagnetic core includes a first F-shaped core and a second F-shaped core arranged in such a way relative to each other so as to form that the first air gap and the second air gap.

19. The current sensor of claim 18, wherein the cutout forms a distance, opposite the second air gap, that is greater than a width of the bus bar.

20. The current sensor of claim 14, wherein the first air gap is spaced from the second air gap, the second air gap being arranged between the first air gap and the cutout.
